(19) United States
(12) Patent Application Publication
(10) Pub. No.: US 2008/0048192 A1
(43) Pub. Date: Feb. 28, 2008

(54) LED devices and associated methods

(76) Inventor: Chien-Min Sung, Taipei County (TW)

Correspondence Address: THORPE NORTH & WESTERN, LLP., 8180 SOUTH 700 EAST, SUITE 350, SANDY, UT, 84070, US

(21) Appl. No.: 11/508,560

(22) Filed: Aug. 22, 2006

(51) Int. Cl. H01L 31/0312

(52) U.S. Cl. 257/77

(57) ABSTRACT

Methods for cooling semiconductor devices having a light-emitting surface and associated devices are disclosed and described. Such a device may include a light-emitting surface and a diamond layer disposed on at least a portion of the light-emitting surface. The diamond layer may be exposed to air in order to accelerate movement of heat away from the light-emitting surface and into the air.

### FIELD OF THE INVENTION

The present invention relates generally to methods and associated devices for cooling semiconductor and other electronics devices. Accordingly, the present invention involves the electrical and material science fields.

### BACKGROUND OF THE INVENTION

In many developed countries, major portions of the populations consider electronic devices to be integral to their lives. Such increasing use and dependence has generated a demand for electronics devices that are smaller and faster. As electronic circuitry increases in speed and decreases in size, cooling of such devices becomes problematic.

Electronic devices generally contain printed circuit boards having integrally connected electronic components that allow the overall functionality of the device. These electronic components, such as processors, transistors, resistors, capacitors, light-emitting diodes (LEDs), etc., generate significant amounts of heat. As it builds, heat can cause various thermal problems associated with such electronic components. Significant amounts of heat can affect the reliability of an electronic device, or even cause it to fail by, for example, causing burn out or shorting both within the electronic components themselves and across the surface of the printed circuit board. Thus, the buildup of heat can ultimately affect the functional life of the electronic device. This is particularly problematic for electronic components with high power and high current demands, as well as for the printed circuit boards that support them.

Various cooling devices have been employed such as fans, heat sinks, Peltier and liquid cooling devices, etc., as means of reducing heat buildup in electronic devices. As increased speed and power consumption cause increasing heat buildup, such cooling devices generally must increase in size to be effective and may also require power to operate. For example, fans must be increased in size and speed to increase airflow, and heat sinks must be increased in size to increase heat capacity and surface area. The demand for smaller electronic devices, however, not only precludes increasing the size of such cooling devices, but may also require a significant size decrease.

As a result, methods and associated devices are being sought to provide adequate cooling of electronic devices while minimizing size and power constraints placed on such devices due to cooling.

### SUMMARY OF THE INVENTION

Accordingly, the present invention provides devices and associated methods for cooling semiconductor devices. In one aspect, for example, a method for cooling a semiconductor device having a light-emitting surface is provided. Such a method may include accelerating movement of heat away from the semiconductor device through a diamond layer applied to the light-emitting surface. Though various devices are contemplated, non-limiting examples may include light-emitting diodes (LEDs), laser diodes, etc.

In one aspect of the present invention, the diamond layer may be configured such that light generated by the light-emitting surface is emitted through the diamond layer. As such, accelerated movement of heat away from the semiconductor device is at least partially due to heat movement laterally through the diamond layer. Additionally, the accelerated movement of heat away from the semiconductor device is at least partially due to heat movement from the diamond layer to air. In one aspect, heat movement from the diamond layer to air is greater than heat movement from the light-emitting surface to air. Additionally, in another aspect heat movement from the light-emitting surface to the diamond layer is greater than heat movement from the light-emitting surface to the air.

The present invention also provides various semiconductor devices. For example, in one aspect a semiconductor device having improved thermal properties is provided. Such a device may include a light-emitting surface and a diamond layer disposed on at least a portion of the light-emitting surface. The diamond layer may be exposed to air in order to accelerate movement of heat away from the light-emitting surface and into the air. Additionally, the diamond layer may include a material that is a member selected from the group consisting of diamond, diamond-like carbon, amorphous diamond, and combinations thereof.

In another aspect, a method of manufacturing the semiconductor devices described herein is provided. Such a method may include providing the semiconductor device having a light-emitting surface and coating a diamond layer on at least a portion of the light-emitting surface in order to accelerate movement of heat away from the light-emitting surface.

In yet another aspect, a method of exceeding a maximum operating wattage of a light-emitting diode is provided. Such a method may include drawing heat from a light-emitting surface of the LED with a diamond layer in order to operate the LED at an operating wattage that is higher than the maximum operating wattage.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-section view of a semiconductor device in accordance with one embodiment of the present invention.

FIG. 2 is a cross-section view of a semiconductor device in accordance with one embodiment of the present invention.

FIG. 3 is a cross-section view of a semiconductor device in accordance with one embodiment of the present invention.

FIG. 4 is a cross-section view of a semiconductor device in accordance with one embodiment of the present invention.

FIG. 5 is a cross-section view of a semiconductor device in accordance with one embodiment of the present invention.

FIG. 6 is a cross-section view of a semiconductor device in accordance with another embodiment of the present invention.

### DETAILED DESCRIPTION OF THE INVENTION

Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a heat source” includes reference to one or more of such sources, and reference to “the diamond layer” includes reference to one or more of such layers.

The terms “heat transfer,” “heat movement,” and “heat transmission” can be used interchangeably, and refer to the movement of heat from an area of higher temperature to an area of cooler temperature. It is intended that the movement of heat include any mechanism of heat transmission known to one skilled in the art, such as, without limitation, conductive, convective, radiative, etc.

As used herein, the term “heat conductive material” refers to any material known to one skilled in the art that is capable of conducting heat at a higher rate than the material on which it is deposited.

As used herein, the term “emitting” refers to the process of moving heat or light from a solid material into the air.

As used herein, “light-emitting surface” refers to a surface of a device or object from which light is intentionally emitted. Light may include visible light and light within the ultraviolet spectrum. An example of a light-emitting surface may include, without limitation, a nitride layer of an LED, or of semiconductor layers to be incorporated into an LED, from which light is emitted.

As used herein, “dynamic” or “dynamically” or “thermally dynamic” refers to a characteristic of a material wherein the material is active at transferring energy. Generally, the dynamic material is active at transferring thermal energy.

As used herein, “vapor deposited” refers to materials which are formed using vapor deposition techniques. “Vapor deposition” refers to a process of depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically depositing diamond particles in a vapor form upon a surface. Various CVD techniques are well known in the art.

As used herein, “physical vapor deposition,” or “PVD” refers to any method of physically depositing diamond particles in a vapor form upon a surface. Various PVD techniques are well known in the art.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including its physical and electrical properties are well known in the art.

As used herein, “distorted tetrahedral coordination” refers to a tetrahedral bonding configuration of carbon atoms that is irregular, or has deviated from the normal tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, tungsten, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

As used herein, “coat,” “coating,” and “coated,” with respect to a surface, refers to an area along at least a portion of an outer surface of the semiconductor device that has been intimately contacted with a layer of heat conductive material, and, as such, thermal coupling has been achieved. In some aspects, the coating may be a layer which substantially covers an entire surface of the semiconductor device. In other aspects, the coating may be a layer which covers only a portion of a surface of the printed circuit board.

As used herein, the term “maximum operating wattage” refers to the maximum wattage that a semiconductor may be reliably operated.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Invention

The present invention provides semiconductor devices and methods of cooling such devices. It has been discovered that materials having high thermal conductivity can be coated onto the surface of a semiconductor device in order to accelerate heat transfer laterally away from hot spots. Many of these materials, particularly diamond materials, also accelerate heat transfer to the air. Thus a semiconductor device can be effectively cooled by accelerated heat transfer laterally across the surface of the device and accelerated heat transfer to the air as it spreads laterally.

Semiconductor devices that emit light are often challenging to cool. Much of the heat generated by such a device may be associated with the surface that emits the light. For example, an LED may consist of a plurality of nitride layers arranged to emit light from a light-emitting surface. Because heat sinks cannot interfere with the function of the nitride layers or the light-emitting surface, they are often located at the junction between the LED and a supporting structure such as a circuit board. Such a heat sink location is relatively remote from the accumulation of much of the heat, namely, the light-emitting surface. The inventor has developed a method for cooling such light-emitting semiconductor devices by coating a heat transferring material on the light-emitting surface to accelerate the movement of heat from the device.

Accordingly, in one aspect of the present invention, a method of cooling a semiconductor device having a light-emitting surface is provided that includes accelerating movement of heat away from the semiconductor device through a diamond layer applied to the light-emitting surface. Any form of light-emitting surface known to generate heat is considered to be within the scope of the present invention. In one aspect the light-emitting surface can be associated with a heat-generating electronic component such as LEDs, lazer diodes, etc.

Thus the transfer of heat present in the semiconductor device can be accelerated away from the light-emitting surface by coating the surface with a diamond layer. It should be noted that the present invention is not limited as to specific theories of heat transmission. As such, in one aspect the accelerated movement of heat away from the light-emitting surface can be at least partially due to heat movement laterally through the diamond layer. Due to the heat conductive properties of diamond, heat can rapidly spread laterally through the diamond layer across the surface of the semiconductor device. In another aspect, the accelerated movement of heat away from the light-emitting surface may be at least partially due to heat movement from the diamond layer to air. For example, a diamond material such as diamond-like carbon (DLC) has exceptional heat emissivity characteristics even at temperatures below 100° C., and as such, may radiate heat directly to the air. Many other materials that comprise the semiconductor device may conduct heat much better than they emit heat. As such, heat can be conducted through the semiconductor materials of the light-emitting surface to the DLC layer and subsequently emitted to the air. Due to the high heat conductive and radiative properties of DLC, heat movement from the DLC layer to air can be greater than heat movement from the light-emitting surface of the semiconductor device to air. Also, heat movement from the semiconductor device to the DLC layer can be greater than heat movement from the semiconductor device to the air. As such, the layer of DLC can serve to accelerate heat transfer away from a light-emitting surface more rapidly than heat can be transferred through the semiconductor device itself, or from the semiconductor device to the air. Such accelerated heat transfer may result in semiconductor devices with much cooler operational temperatures. Additionally, the acceleration of heat transfer away from a light-emitting surface not only cools the semiconductor device, but may also reduce the heat load on many electronic components that are spatially located near the semiconductor device.

Because the diamond layer is coated onto the light-emitting surface of the device, in various aspects it may be beneficial for the diamond layer to transmit light therethrough. As such, in one aspect the diamond layer may be transparent to light. In another aspect, the diamond layer may be at least translucent to light.

Various diamond materials may be utilized to provide accelerated heat transferring properties to a semiconductor device. Non-limiting examples of such diamond materials may include diamond, DLC, amorphous diamond, and combinations thereof. It should be noted, however, that any form of natural or synthetic diamond material that may be utilized to cool a semiconductor device is considered to be within the present scope.

Generally, diamond layers may be formed by any means known, including various vapor deposition techniques. Any number of known vapor deposition techniques may be used to form these diamond layers. The most common vapor deposition techniques include CVD and PVD, although any similar method can be used if similar properties and results are obtained. In one aspect, CVD techniques such as hot filament, microwave plasma, oxyacetylene flame, rf-CVD, laser CVD (LCVD), metal-organic CVD (MOCVD), laser ablation, conformal diamond coating processes, and direct current arc techniques may be utilized. Typical CVD techniques use gas reactants to deposit the diamond or diamond-like material in a layer, or film. These gases generally include a small amount (i.e. less than about 5%) of a carbonaceous material, such as methane, diluted in hydrogen. A variety of specific CVD processes, including equipment and conditions, as well as those used for boron nitride layers, are well known to those skilled in the art. In another aspect, PVD techniques such as sputtering, cathodic arc, and thermal evaporation may be utilized. Further, specific deposition conditions may be used in order to adjust the exact type of material to be deposited, whether DLC, amorphous diamond, or pure diamond. It should also be noted that many semiconductor devices such as LEDs may be degraded by high temperature. Care man need to be taken to avoid damage during diamond deposition by depositing at lower temperatures. For example, if the semiconductor contains InN, deposition temperatures of up to about 600° C. may be used. In the case of GaN, layers may be thermally stable up to about 1000° C. Additionally, preformed layers can be brazed, glued, or otherwise affixed to the light-emitting surface of the semiconductor device using methods which do not unduly interfere with the heat transference diamond layer or light emission of the device.

In one aspect of the present invention, the diamond layer may be a conformal diamond layer. Conformal diamond coating processes can provide a number of advantages over conventional diamond film processes. Conformal diamond coating can be performed on a wide variety of substrates, including non-planar substrates. A growth surface can be pretreated under diamond growth conditions in the absence of a bias to form a carbon film.

The diamond growth conditions can be conditions that are conventional CVD deposition conditions for diamond without an applied bias. As a result, a thin carbon film can be formed which is typically less than about 100 angstroms. The pretreatment step can be performed at almost any growth temperature such as from about 200° C. to about 900° C., although lower temperatures below about 500° C. may be preferred. Without being bound to any particular theory, the thin carbon film appears to form within a short time, e.g., less than one hour, and is a hydrogen terminated amorphous carbon.

Following formation of the thin carbon film, the light-emitting surface may then be subjected to diamond growth conditions to form the diamond film as a conformal diamond film. The diamond growth conditions may be those conditions which are commonly used in traditional CVD diamond growth. However, unlike conventional diamond film growth, the diamond film produced using the above pretreatment steps results in a conformal diamond film. Further, the diamond film typically begins growth substantially over the entire substrate with substantially no incubation time. In addition, a continuous film, e.g. substantially no grain boundaries, can develop within about 80 nm of growth.

The diamond layer may be of any thickness that would allow cooling according to the methods and devices of the present invention. Thicknesses may vary depending on the application and the semiconductor device configuration. For example, greater cooling requirements may require a thicker diamond layer. The thickness may also vary depending on the material used in the diamond layer. That being said, in one aspect the diamond layer may be from about 0.1 micrometer to about 50 micrometers thick. In another aspect, the diamond layer may be from about 0.1 micrometer to about 10 micrometers thick.

The present invention also provides semiconductor devices having improved thermal properties. In one aspect, such devices may include a light-emitting surface and a diamond layer disposed on at least a portion of the light-emitting surface. The light-emitting surface may be exposed to the air in order to accelerate movement of heat away from the light-emitting surface and into the air. It is contemplated that the diamond layer may be disposed onto the light-emitting surface of the semiconductor device during manufacture, or the diamond layer may be disposed onto an existing semiconductor device after manufacture.

Any semiconductor device capable of emitting light is considered to be within the scope of the present invention. For example, and without limitation, the semiconductor device may be an LED, a laser diode, etc. Though much of the following discussion is directed to LEDs, it should be understood that the present scope extends to all light-emitting semiconductor devices. Additionally, the present scope should not be limited to the types of LEDs described herein, but should encompass all configurations of such devices.

As they have become increasingly important in electronics and lighting devices, LEDs continue to be developed that have ever increasing power requirements. This trend of increasing power has created cooling problems for these devices. These cooling problems can be exacerbated by the typically small size of these devices, which may render heat sinks with traditional aluminum heat fins ineffective due to their bulky nature. Additionally, such traditional heat sinks would block the emission of light if applied to the light-emitting surface of the LED. The inventor has discovered that applying a layer of diamond to the light-emitting surface of an LED device allows adequate cooling even at very high power, while maintaining a small LED package size. Additionally, in one aspect the maximum operating wattage of an LED may be exceeded by drawing heat from the light-emitting surface of the LED with a diamond layer in order to operate the LED at an operating wattage that is higher than the maximum operating wattage for that LED.

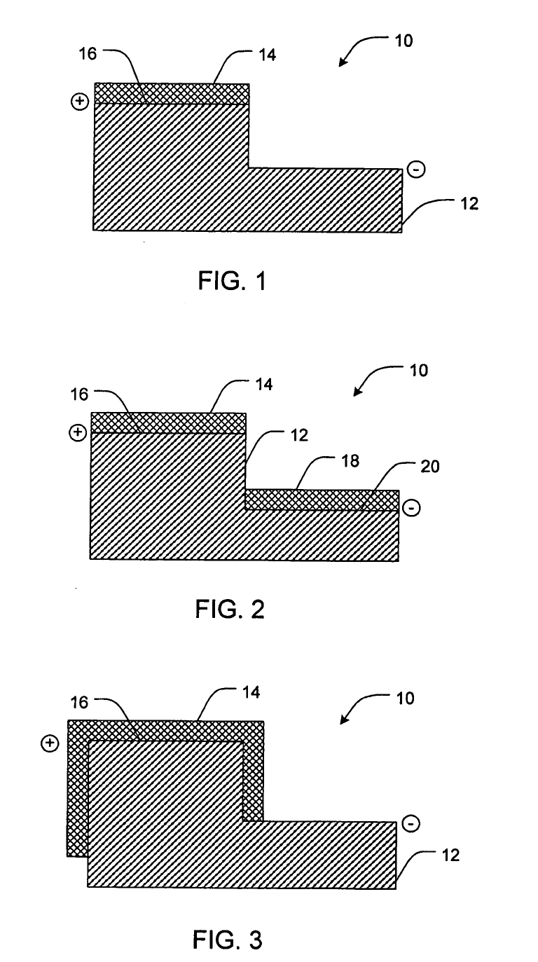

Two main configurations of LED devices are commonly used. In one configuration, as shown in FIG. 1, the anode and the cathode are on the same side of the semiconductor layers 12. A diamond layer 14 is disposed onto the light-emitting surface 16 of the LED 10. The diamond layer 14 is thus thermally coupled to the light-emitting surface 16. As such, when the LED 10 is functioning, light is emitted from the light-emitting surface 16. As a result, heat is generally accumulated at the light-emitting surface 16 and in the semiconductor layers 12. The diamond layer 14 accelerates the transfer of heat both laterally through the diamond layer 14 and into the air. Such a transmission of heat allows the LED 10 to operate at cooler temperatures.

In addition to applying the diamond layer to the light-emitting surface, further improvements in heat dissipation may be achieved by applying the diamond layer to other surfaces of the LED. As shown in FIG. 2, for example, in addition to the light-emitting surface 16, an additional diamond layer 18 may be applied to an anode surface 20 of the semiconductor layers 12. Additionally, as shown in FIG. 3, the diamond layer 14 may extend beyond the light-emitting surface 16 of the LED 10, in this case onto the sides of the semiconductor layers 12. By extending the diamond layer beyond the light-emitting surface, heat can be drawn from a greater portion of the semiconductor layers, thus improving the heat dissipation characteristics of the device. It should be noted that any portion of the LED device can similarly be coated with a diamond layer to improve heat dissipation properties.

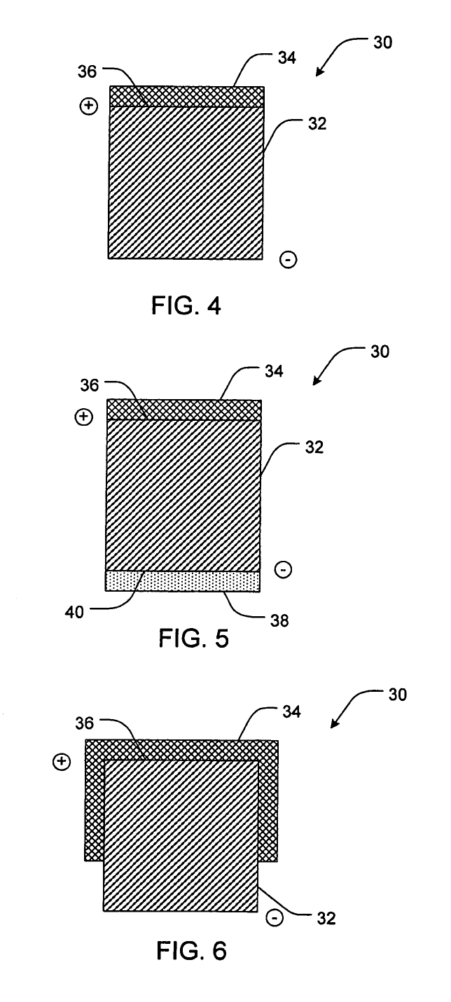

In another LED configuration, as shown in FIG. 4, the anode and the cathode are on opposite sides of the semiconductor layers 32. A diamond layer 34 is disposed onto the light-emitting surface 36 of the LED 30. As with the previous configuration, the diamond layer 34 is thermally coupled to the light-emitting surface 36, and as a result, as a result, heat that is accumulated at the light-emitting surface 36 and in the semiconductor layers 32 is transferred from the LED 30 to the air via the diamond layer 34.

In addition to applying the diamond layer to the light-emitting surface, further improvements in heat dissipation may be achieved by similarly applying the diamond layer to other surfaces of the LED. As shown in FIG. 5, for example, in addition to the light-emitting surface 36, an additional diamond layer 38 may be applied to an additional surface 40 of the semiconductor layers 32. Because some light may be emitted from the anode surface 40 through the LED, a reflective layer may be applied to the additional surface 40 prior to application of the additional diamond layer 38 to reflect light back through the LED. One example of a reflective material that may be used to create such a layer is Cr. It should be noted that such application of reflective material may be useful in various aspects of the present invention in order to direct light through the LED in a particular direction. Additionally, in some cases, application of the diamond layer to a light-emitting surface may not necessarily include the surface from which a majority of light is to be emitted from. For example, in one aspect an LED as shown in FIG. 5 may include a diamond layer along the surface shown at 40 but not along the surface shown at 36.

Additionally, as shown in FIG. 6, the diamond layer 34 may extend beyond the light-emitting surface 36 of the LED 30, in this case onto the sides of the semiconductor layers 32. As was described above, extending the diamond layer beyond the light-emitting surface may more effectively draw heat from a greater portion of the semiconductor layers to improve the heat dissipation characteristics of the device. It should be noted that any portion of the LED device can similarly be coated with a diamond layer to improve heat dissipation properties.

### EXAMPLES

The following examples illustrate various techniques of making an LED according to aspects of the present invention. However, it is to be understood that the following are only exemplary or illustrative of the application of the principles of the present invention. Numerous modifications and alternative compositions, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

A GaN LED crystal is formed on a sapphire substrate. A diamond film is coated on top of the GaN layer. The diamond film is deposited by microwave enhanced plasma CVD with methane (1%) and hydrogen (99%) as the gas mixture (100 torr). The diamond film is then sputter coated with Cr as a reflector and brazed to a silicon holder. Subsequently, the sapphire substrate is removed by light bombardment at the interface with an eximer laser. The diamond coated LED is deposited with second diamond film along the surface that previously contained the sapphire layer. The LED is thus sandwiched between two diamond films so the heat can be removed readily from both sides.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of cooling a semiconductor device having a light-emitting surface, comprising:
accelerating movement of heat away from the semiconductor device through a diamond layer applied to the light-emitting surface.

2. The method of claim 1, wherein the semiconductor device is a light-emitting diode.

3. The method of claim 1, wherein the semiconductor device is a laser diode.

4. The method of claim 1, wherein light generated by the light-emitting surface is emitted through the diamond layer.

5. The method of claim 4, wherein the diamond layer is transparent.

6. The method of claim 1, wherein the diamond layer is exposed to air.

7. The method of claim 1, wherein the accelerated movement of heat away from the semiconductor device is at least partially due to heat movement laterally through the diamond layer.

8. The method of claim 1, wherein the accelerated movement of heat away from the semiconductor device is at least partially due to heat movement from the diamond layer to air.

9. The method of claim 8, wherein heat movement from the diamond layer to air is greater than heat movement from the light-emitting surface to air.

10. The method of claim 1, wherein heat movement from the light-emitting surface to the diamond layer is greater than heat movement from the light-emitting surface to the air.

11. A semiconductor device having improved thermal properties, comprising:
a light-emitting surface; and
a diamond layer disposed on at least a portion of the light-emitting surface and exposed to air in order to accelerate movement of heat away from the light-emitting surface and into the air.

12. The device of claim 11, wherein the semiconductor device is a light-emitting diode.

13. The device of claim 11, wherein the semiconductor device is a laser diode.

14. The device of claim 11, wherein the diamond layer includes a member selected from diamond, diamond-like carbon, amorphous diamond, and combinations thereof.

15. The device of claim 11, wherein light from the light-emitting surface is emitted through the diamond layer.

16. The device of claim 15, wherein the diamond layer is transparent.

17. A method of manufacturing the semiconductor device of claim 11, comprising:
providing the semiconductor device having a light-emitting surface;
coating a diamond layer on at least a portion of the light-emitting surface of the semiconductor device in order to accelerate movement of heat away from the light-emitting surface.

18. The method of claim 17, wherein the semiconductor device is a light-emitting diode.

19. The method of claim 17, wherein the semiconductor device is a laser diode.

20. The method of claim 17, wherein light generated by the light-emitting surface is emitted through the diamond layer.

21. The method of claim 17, wherein coating the diamond layer further includes depositing the diamond layer as conformal diamond coating.

22. A method of exceeding a maximum operating wattage of a light-emitting diode, comprising:
drawing heat from a light-emitting surface of the light-emitting diode with a diamond layer in order to operate the light-emitting diode at an operating wattage that is higher than the maximum operating wattage.
